(19) United States
(12) Patent Application Publication
(10) Pub. No.: US 2025/0226252 A1
(43) Pub. Date: Jul. 10, 2025

(54) BATCH-TYPE SUBSTRATE PROCESSING APPARATUS

(71) Applicant: SAMSUNG ELECTRONICS CO., LTD., Suwon-si (KR)

(72) Inventors: Sekeun KWAK, Suwon-si (KR); Sungman LEE, Suwon-si (KR)

(73) Assignee: SAMSUNG ELECTRONICS CO., LTD., Suwon-si (KR)

(21) Appl. No.: 18/982,599

(22) Filed: Dec. 16, 2024

(30) Foreign Application Priority Data
Jan. 5, 2024 (KR) 10-2024-0002439

(51) Int. Cl. H01L 21/673; H01L 21/56; H01L 21/67; H01L 21/677

(52) U.S. Cl. CPC H01L 21/67303; H01L 21/561; H01L 21/67098; H01L 21/67766

(57) ABSTRACT

Provided is a batch-type substrate processing apparatus including an outer tube having a cylindrical shape with a central axis disposed in a vertical direction, an inner tube having a cylindrical shape with a central axis disposed in the vertical direction within the outer tube, a manifold having a cylindrical shape and supporting lower ends of the inner tube and the outer tube, an inner tube support ring disposed below the inner tube and supporting the inner tube, and an inner tube guide ring disposed below the inner tube support ring and supporting the inner tube support ring. The inner tube guide ring includes a guide ring body and a protrusion protruding from the guide ring body in the vertical direction, and the protrusion is configured to seal between an interior of the manifold and an outer portion of the inner tube support ring.

### CROSS-REFERENCE TO RELATED APPLICATION

This application is based on and claims priority to Korean Patent Application No. 10-2024-0002439, filed on Jan. 5, 2024, in the Korean Intellectual Property Office, the disclosure of which is incorporated by reference herein in its entirety.

### BACKGROUND

### 1. Field

The disclosure relates to a substrate processing apparatus, and more particularly, to a batch-type substrate processing apparatus.

### 2. Description of Related Art

The process of manufacturing a semiconductor device may include a substrate processing process, e.g., a process of forming thin-films on a plurality of substrates or heat-treating on a plurality of substrates. A substrate processing process can be performed in a batch-type substrate processing apparatus capable of processing a plurality of substrates. A batch-type substrate processing apparatus may include a boat capable of mounting and stacking a plurality of substrates thereon and a process tube capable of processing substrates mounted in the boat.

### SUMMARY

Provided is a batch-type substrate processing apparatus capable of supporting a process tube, uniformly processing a plurality of substrates in the process tube, and suppressing contamination of the batch-type substrate processing apparatus caused by reaction by-products in the process tube.

According to an aspect of the disclosure, a batch-type substrate processing apparatus includes: an outer tube having a cylindrical shape with a central axis disposed in a vertical direction; an inner tube within the outer tube, the inner tube having a cylindrical shape with a central axis disposed in the vertical direction; a manifold having a cylindrical shape, wherein the manifold supports a lower end of the inner tube and a lower end of the outer tube; an inner tube support ring below the inner tube, wherein the inner tube support ring supports the inner tube; and an inner tube guide ring below the inner tube support ring, wherein the inner tube guide ring supports the inner tube support ring, wherein the inner tube guide ring includes a guide ring body and a protrusion protruding from the guide ring body in the vertical direction, and wherein the protrusion forms a seal between an interior of the manifold and an outer portion of the inner tube support ring.

According to an aspect of the disclosure, a batch-type substrate processing apparatus includes: an outer tube having a cylindrical shape with a central axis disposed in a vertical direction; an inner tube within the outer tube, the inner tube having a cylindrical shape with a central axis disposed in the vertical direction; a manifold having a cylindrical shape, wherein the manifold supports a lower end of the inner tube and a lower end of the outer tube, wherein the manifold includes an inward flange having a ring-like shape, the inward flange protruding inward toward an interior of the manifold, and wherein the inward flange includes an upper inward flange and a lower inward flange spaced apart from the upper inward flange in the vertical direction; an inner tube support ring below the inner tube, wherein the inner tube support ring supports the inner tube; and an inner tube guide ring below the inner tube support ring, wherein the inner tube guide ring supports the inner tube support ring, and wherein the inner tube guide ring is below the upper inward flange and the lower inward flange, wherein the inner tube guide ring includes a guide ring body and a protrusion protruding from the guide ring body in the vertical direction, and wherein the protrusion forms a seal between an interior of the manifold and an outer portion of the inner tube support ring.

According to an aspect of the disclosure, a batch-type substrate processing apparatus includes: an outer tube having a closed upper end and a cylindrical shape with a central axis disposed in a vertical direction; an inner tube inside of the outer tube, the inner tube having a closed upper end and a cylindrical shape with a central axis disposed in the vertical direction, wherein an annular space is formed between the inner tube and the outer tube, and wherein a length of the inner tube in the vertical direction is different from a length of the outer tube in the vertical direction; a manifold having a cylindrical shape, wherein the manifold supports a lower end of the inner tube and a lower end of the outer tube, and wherein the manifold includes: an upper flange, the upper flange protruding outward from the manifold and supporting the lower end of the outer tube at an upper end of the manifold; and an inward flange having a ring-like shape, the inward flange protruding inward toward an interior of the manifold from a middle portion of the manifold, wherein the inward flange includes an upper inward flange and a lower inward flange spaced apart from the upper inward flange in the vertical direction; an inner tube support ring below the inner tube, wherein the inner tube support ring supports the inner tube; and an inner tube guide ring below the inner tube support ring, wherein the inner tube guide ring supports the inner tube support ring, wherein the inner tube guide ring is below the upper inward flange and the lower inward flange, wherein the inner tube guide ring includes a guide ring body and a protrusion protruding from the guide ring body in the vertical direction, and wherein the protrusion forms a seal between an interior of the manifold and an outer portion of the inner tube support ring.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a schematic cross-sectional view of a batch-type substrate processing apparatus according to an embodiment;

FIG. 2 is a partially enlarged cross-sectional view for schematically describing the coupling relationship between a manifold, an inner tube support ring, and an inner tube guide ring of the batch-type substrate processing apparatus of FIG. 1;

FIGS. 3 and 5 are enlarged plan views schematically illustrating components arranged within a manifold of the batch-type substrate processing apparatus of FIG. 1;

FIG. 4 is a plan view illustrating an inner tube support ring disposed within the manifold of FIGS. 3 and 5;

FIG. 6 is a plan view of an inner tube guide ring disposed within a manifold of a batch-type substrate processing apparatus of FIG. 1;

FIG. 7 is a partially enlarged view of the inner tube guide ring of FIG. 6;

FIG. 8 is a partially enlarged cross-sectional view of the inner tube guide ring of FIG. 6;

FIG. 9 is a plan view of an inner tube guide ring disposed within a manifold of a batch-type substrate processing apparatus according to an embodiment;

FIG. 10 is a cross-sectional view illustrating the flow of reaction by-products formed inside a manifold of a batch-type substrate processing apparatus according to an embodiment;

FIG. 11 is a cross-sectional view illustrating the flow of reaction by-products formed inside a manifold of a batch-type substrate processing apparatus according to a comparative example to be compared with the disclosure; and

FIG. 12 is a partially enlarged cross-sectional view for schematically describing the coupling relationship between an inner tube support ring and an inner tube guide ring at a left portion and a right portion of a manifold of the batch-type substrate processing apparatus of FIG. 1.

### DETAILED DESCRIPTION

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

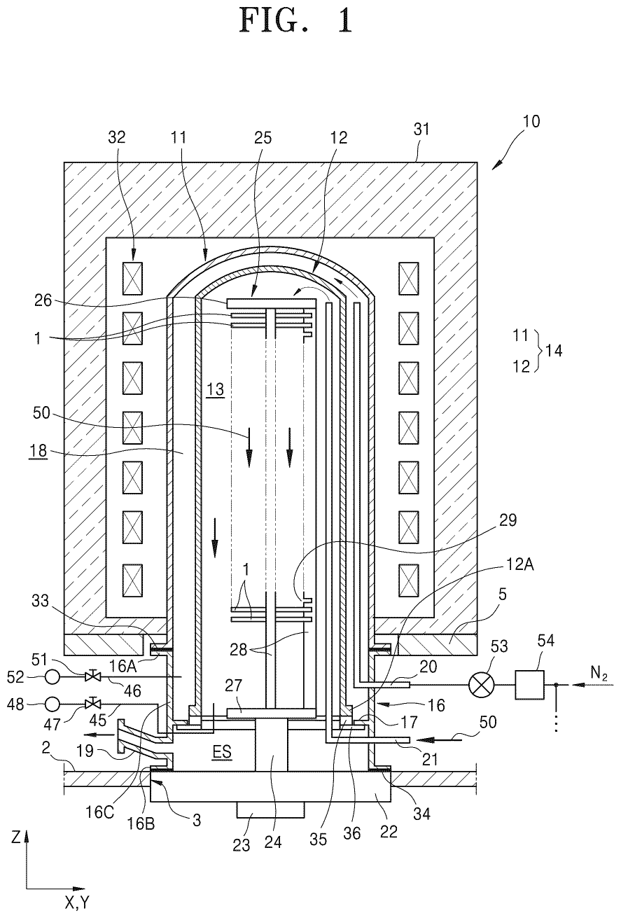

FIG. 1 is a schematic cross-sectional view of a batch-type substrate processing apparatus according to an embodiment.

Specifically, a batch-type substrate processing apparatus 10 may be used in a method of manufacturing a semiconductor device (or a semiconductor integrated circuit device). The batch-type substrate processing apparatus 10 may be an apparatus for forming a thin-film, e.g., a silicon oxide film, a silicon nitride film, or a polysilicon film, on a substrate 1, e.g., a silicon wafer, or heat-treating a thin-film or an ion-implanted material layer formed on the substrate 1.

The batch-type substrate processing apparatus 10 may be an apparatus for chemical vapor deposition, an apparatus for atomic layer deposition, or a furnace. The batch-type substrate processing apparatus 10 may be a film forming apparatus. The batch-type substrate processing apparatus 10 may include an inner tube 12 and an outer tube 11. The inner tube 12 and the outer tube 11 may be referred to as a process tube 14.

The batch-type substrate processing apparatus 10 may be an apparatus for carrying in (or loading) the substrate 1, e.g., a silicon wafer, into the inner tube 12 and processing the substrate 1 by supplying a processing gas into the inner tube 12 and simultaneously heating the interior of the inner tube 12 with a heater 32.

The batch-type substrate processing apparatus 10 includes a vertical type outer tube 11 whose central axis is arranged in a vertical direction (Z direction). The batch-type substrate processing apparatus 10 includes the inner tube 12 whose central axis is arranged in the vertical direction (Z direction) inside the outer tube 11.

In the inner tube 12, a film may be deposited on a plurality of substrates 1 mounted on a boat 25 or heat treatment may be performed on the plurality of substrates 1. An annular space 18 may be located between the outer tube 11 and the inner tube 12.

According to one or more embodiments, the outer tube 11 may include quartz and may have a cylindrical shape with a closed upper end. According to one or more embodiments, the inner tube 12 may include silicon carbide (SiC) or quartz. According to one or more embodiments, the inner tube 12 may have a cylindrical shape with a closed upper end. According to one or more embodiments, the inner tube 12 may have a cylindrical shape with an open upper end, unlike that of FIG. 1. The inner tube 12 may have a diameter smaller than that of the outer tube 11.

According to one or more embodiments, the length of the inner tube 12 may be different from that of the outer tube 11 in the vertical direction (Z direction). According to one or more embodiments, the length of the inner tube 12 may be greater than that of the outer tube 11 in the vertical direction (Z direction). According to one or more embodiments, the length of the inner tube 12 may be equal to or shorter than that of the outer tube 11 in the vertical direction (Z direction).

The batch-type substrate processing apparatus 10 may include a manifold 16 that supports lower ends of the inner tube 12 and the outer tube 11. The manifold 16 may be configured in a cylindrical shape. The outer tube 11 may be sealed with the manifold 16 by using a first sealant 33. The outer tube 11 may be a pressure-resistant container capable of withstanding a certain pressure.

The internal space of the inner tube 12 may correspond to a processing chamber 13 into which a plurality of stacked substrates 1 are carried in (or loaded) by the boat 25. The bottom opening of the inner tube 12 may be an entrance for bringing the boat 25 in and out. The outer tube 11 is fixed to the upper end of the manifold 16.

The manifold 16 includes an upper flange 16A at an upper end thereof that protrudes outward in the radial direction (X direction or Y direction). The upper flange 16A may support the lower end of the outer tube 11. The manifold 16 includes a lower flange 16B at a lower end thereof that protrudes outward in the radial direction (X direction or Y direction).

The manifold 16 includes an inward flange 17 that protrudes inward in the radial direction (X direction or Y direction) from a middle portion 16C. The manifold 16, the upper flange 16A, and the lower flange 16B may constitute one body.

The inward flange 17 may be configured in a ring-like shape. In the internal space of the manifold 16, the space between the inward flange 17 and the top surface of a seal cap 22 may correspond to an exhaust space ES. The lower end of the outer tube 11 is supported by the upper flange 16A of the manifold 16 via the first sealant 33.

The lower flange 16B of the manifold 16 is supported by the top surface of the seal cap 22 via a second sealant 34. The lower flange 16B of the manifold 16 serves as a seal for the manufacturing process via the second sealant 34. Through the outer wall of the manifold 16, an exhaust pipe 19 that communicates with the exhaust space ES is provided below the inward flange 17. An exhaust device that exhausts gas inside the exhaust space ES may be connected to the exhaust pipe 19.

An inner tube flange 12A protruding outward in the radial direction is integrally formed at the lower end of the inner tube 12. The outer diameter of the inner tube flange 12A may be smaller than the inner diameter of the inward flange 17. The inner tube 12 may pass inside the inward flange 17 of the manifold 16 in the axial direction (i.e., the vertical or Z direction).

An inner tube support ring 35 supporting the inner tube 12 may be disposed below the inner tube 12 and the inner tube flange 12A. An inner tube guide ring 36 supporting the inner tube support ring 35 may be disposed below the inner tube support ring 35.

The outer diameter of the inner tube guide ring 36 may be formed to be greater than the inner diameter of the inward flange 17, and the inner tube guide ring 36 may be in contact with the bottom surface of the inward flange 17. The inner tube guide ring 36 may be fixed to the inner tube support ring 35 with a screw. The inner tube support ring 35 and the inner tube guide ring 36 will be described in more detail later.

A processing gas nozzle 21 extends through the sidewall of the manifold 16. The processing gas nozzle 21 extends through the sidewall of the manifold 16 at a position lower than that of the inward flange 17. There may be a plurality of processing gas nozzles 21. The opening of the processing gas nozzle 21 may be disposed at the upper end of the processing chamber 13 or on a side of the substrate 1. The processing gas nozzle 21 may include the same material as the outer tube 11 or a different material.

The processing gas nozzle 21 may be connected to a processing gas supply device that supplies a processing gas. A processing gas 50 may be supplied from the processing gas supply device, and the processing gas 50 may be ejected into the processing chamber 13 from the opening of the processing gas nozzle 21. The processing gas 50 introduced into the processing chamber 13 by the processing gas nozzle 21 may pass through the processing chamber 13 and be exhausted to the outside through the exhaust space ES and the exhaust pipe 19. The processing gas may include a raw material gas or a pre-processing gas.

A purge gas nozzle 20 extends through the sidewall of the manifold 16. The opening of the purge gas nozzle 20 may be disposed at the upper end of the annular space 18. The opening of the purge gas nozzle 20 may be at the same position as that of the processing gas nozzle 21. A purge gas supply device that supplies nitrogen gas as an inert gas is connected to the purge gas nozzle 20. An inert gas introduced into the upper portion of the annular space 18 and the processing chamber 13 by the purge gas nozzle 20 may be exhausted through the annular space 18 and the exhaust space ES.

The purge gas supply device is configured by connecting a control valve 53 and a flux controller 54 in series and supplying nitrogen gas from a nitrogen gas source to the purge gas nozzle 20 at a certain mass and a certain flow rate.

A first pipe 45 penetrates through the manifold 16. According to one or more embodiments, unlike in FIG. 1, the first pipe 45 may be installed to penetrate through the exhaust pipe 19. A portion of the first pipe 45 is disposed in the processing chamber 13. At the other portion of the first pipe 45, a first pressure gauge 48 is installed through a first on-off valve 47. The internal pressure of the processing chamber 13 may be detected by using the first pressure gauge 48. The first on-off valve 47 may be opened as needed, e.g., to use the first pressure gauge 48.

A second pipe 46 penetrates through the manifold 16. A portion of the second pipe 46 may be disposed in the annular space 18. At the other portion of the second pipe 46, a second pressure gauge 52 is installed through a second on-off valve 51. The internal pressure of the annular space 18 may be detected by the second pressure gauge 52. The second on-off valve 51 may be opened as needed, e.g., to use the second pressure gauge 52.

The batch-type substrate processing apparatus 10 may include the seal cap 22 that supports the manifold 16. The seal cap 22 may block a boat entry/exit port 3 during a manufacturing process. The batch-type substrate processing apparatus 10 may block the boat entry/exit port by a shutter 2 when a manufacturing process is not in progress.

Furthermore, the seal cap 22 of the batch-type substrate processing apparatus 10 may support the boat 25 for a manufacturing process. The seal cap 22 may be raised by a boat elevator during a manufacturing process to seal the lower end of the manifold 16, and may be lowered by the boat elevator when the manufacturing process is completed. When the seal cap 22 is completely lowered, the shutter 2 may seal the lower end of the manifold 16 to prevent the introduction of external air.

A rotating shaft 24 is installed on the upper portion of the seal cap 22, and an actuator 23 is installed on the lower portion of the seal cap 22. The seal cap 22 and the actuator 23 may be raised and lowered by a boat elevator. The seal cap 22 is formed in a disk-like shape.

The batch-type substrate processing apparatus 10 may include the boat 25. The boat 25 includes a pair of end plates, i.e., an upper end plate 26 and a lower end plate 27, and three to six holding members 28 arranged vertically between the upper end plate 26 and the lower end plate 27. In the three to six holding members 28, a plurality of holding grooves 29 are arranged at equal intervals in the vertical direction (lengthwise direction).

The boat 25 is designed to hold the plurality of substrates 1 by inserting the substrates 1 into the holding grooves 29 of the three to six holding members 28. The boat 25 may include the same material as the outer tube 11 or a different material.

The outer portion of the outer tube 11 is entirely covered with a heat insulation cover 31, and the heater 32 that heats the interior of the outer tube 11 is installed to surround the outer tube 11 inside the heat insulation cover 31. According to one or more embodiments, the heat insulation cover 31 and the heater 32 may be supported vertically by a support 5. The heater 32 is divided into a plurality of heater units, and these heater units are configured to be controlled by a temperature controller.

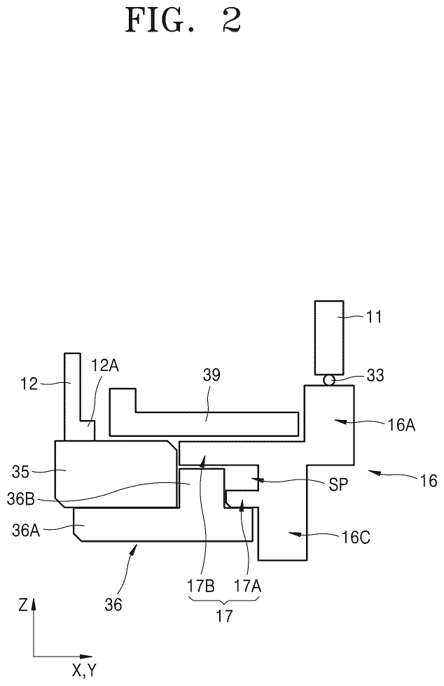

FIG. 2 is a partially enlarged cross-sectional view for schematically describing the coupling relationship between a manifold, an inner tube support ring, and an inner tube guide ring of the batch-type substrate processing apparatus of FIG. 1.

Specifically, the batch-type substrate processing apparatus 10 of FIG. 1 may include the manifold 16, the inner tube support ring 35, and the inner tube guide ring 36, as described above. The manifold 16 may be configured in a cylindrical shape. The manifold 16 may include a metal. FIG. 2 shows a right end of the manifold 16.

The manifold 16 includes the upper flange 16A at its upper end that protrudes outward in the radial direction (X direction or Y direction). The lower end of the outer tube 11 is supported by the upper flange 16A via the first sealant 33. The manifold 16 includes the inward flange 17 that protrudes inward in the radial direction (X direction or Y direction) from a middle portion 16C (i.e., inward flange 17 protrudes toward an interior of the manifold 16). The manifold 16 and the inward flange 17 may be integrated as one body.

The inward flange 17 may be configured in a ring-like shape. The inward flange 17 may include an upper inward flange 17B directly connected to the upper flange 16A and a lower inward flange 17A disposed to be spaced apart from the upper inward flange 17B in the vertical direction (Z direction). There may be an empty space SP between the upper inward flange 17B and the lower inward flange 17A. The inner diameter of the upper inward flange 17B may be smaller than the inner diameter of the lower inward flange 17A.

The inner tube 12 and the inner tube flange 12A may be arranged inside the inward flange 17. The inner tube support ring 35 supporting the inner tube 12 may be disposed below the inner tube 12 and the inner tube flange 12A. The inner tube support ring 35 may support the inner tube 12 and the inner tube flange 12A. The inner tube support ring 35 may include a metal.

According to one or more embodiments, the inner tube support ring 35 may be engaged with the inward flange 17. According to one or more embodiments, a manifold cover 39 may be positioned on the inward flange 17. The upper inward flange 17B may support the manifold cover 39. The manifold cover 39 may be omitted as needed.

The inner tube guide ring 36 supporting the inner tube support ring 35 may be disposed below the inner tube support ring 35. The outer diameter of the inner tube guide ring 36 may be greater than the outer diameter of the inner tube support ring 35. The inner tube guide ring 36 may be formed to be larger than the inner diameter of the inward flange 17, that is, the lower inward flange 17A.

The inner tube guide ring 36 may be located below the upper inward flange 17B and the lower inward flange 17A. The inner tube guide ring 36 may be in contact with the bottom surfaces of the upper inward flange 17B and the lower inward flange 17A. The inner tube guide ring 36 may be fixed to the inner tube support ring 35 with a screw. The inner tube guide ring 36 may include a metal.

The inner tube guide ring 36 may include a guide ring body 36A and a protrusion 36B protruding in the vertical direction (Z direction) from the guide ring body 36A. The protrusion 36B may be configured to seal between the inside of the manifold 16 and the outside of the inner tube support ring 35. A plurality of protrusions 36B may be provided in a plan view. The protrusion 36B may be located on one side of the inner tube support ring 35.

The protrusions 36B may be located outside the inner tube support ring 35, below the upper inward flange 17B, and inside the lower inward flange 17A. The outer diameter of the protrusion 36B may be smaller than the inner diameter of the lower inward flange 17A. The protrusion 36B may contact the empty space SP between the upper inward flange 17b and the lower inward flange 17A of the manifold 16 and may seal the empty space SP.

During a manufacturing process of a semiconductor device, the protrusions 36B may prevent reaction by-products formed inside the process tube (14 of FIG. 1) including the inner tube 12 and the outer tube 11 from being discharged through the empty space SP between the upper inward flange 17B and the lower inward flange 17A.

Also, the batch-type substrate processing apparatus (10 of FIG. 1) may uniformly adjust the separation distance between the inward flange 17 (i.e., the lower inward flange 17A) and the inner tube guide ring 36 through the protrusion 36B.

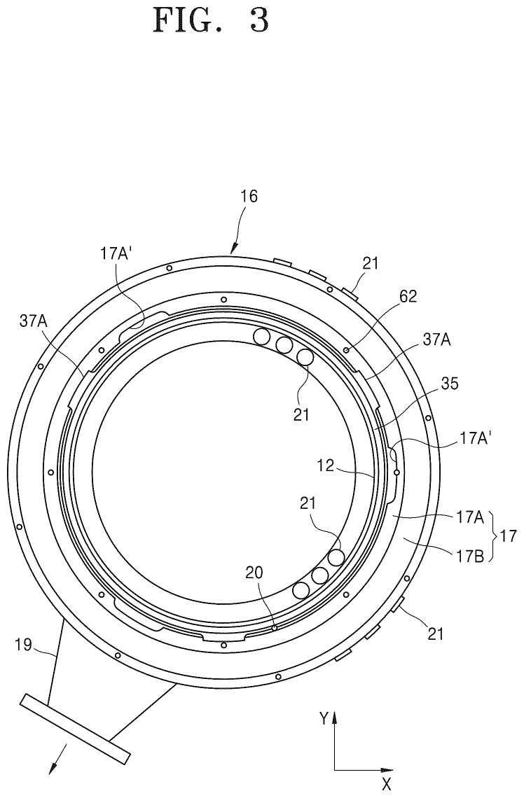

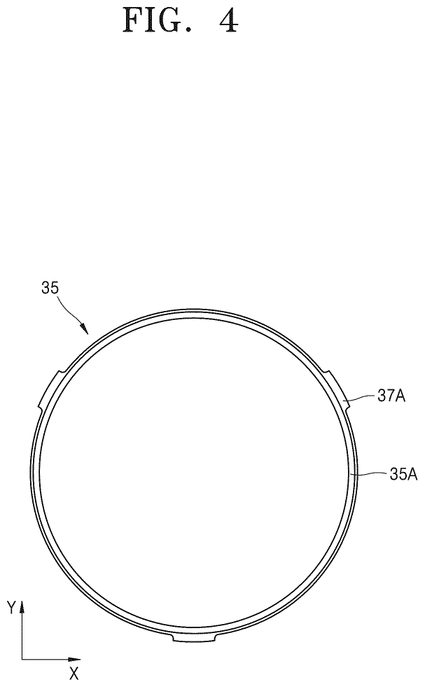

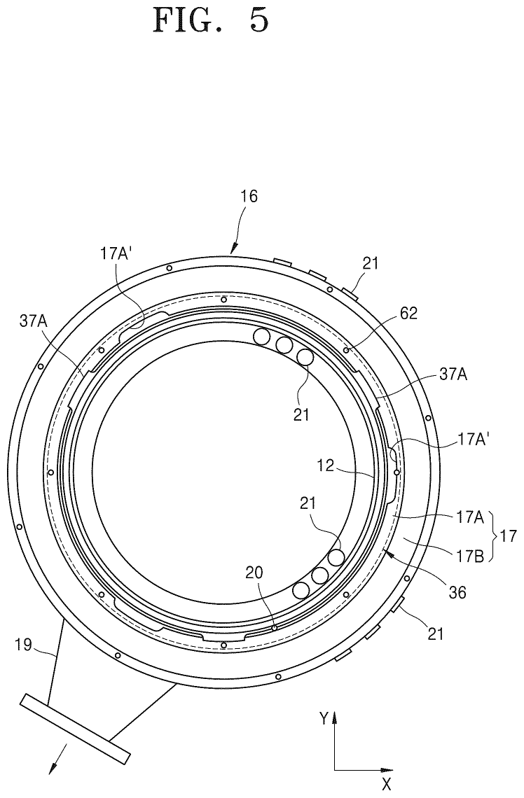

FIGS. 3 and 5 are enlarged plan views schematically illustrating components arranged within a manifold of the batch-type substrate processing apparatus of FIG. 1, and FIG. 4 is a plan view illustrating an inner tube support ring disposed within the manifold of FIGS. 3 and 5.

Specifically, FIGS. 3 and 5 provide plan views of the middle portion (16C of FIGS. 1 and 2) of the manifold 16 for convenience. FIG. 3 illustrates the inner tube support ring 35 for convenience of explanation. FIG. 5 illustrates the inner tube support ring 35 and the inner tube guide ring 36 for convenience of explanation.

As shown in FIG. 3, the batch-type substrate processing apparatus (10 of FIG. 1) may have the inner tube 12 disposed within the manifold 16. The inner tube 12 may be disposed in a cylindrical shape. The processing gas nozzle 21 extends through the sidewall of the manifold 16 at a position lower than that of the inward flange 17. The processing gas nozzle 21 may be disposed inside the inner tube 12. A plurality of processing gas nozzles 21 may be installed. The purge gas nozzle 20 may be disposed outside the inner tube 12.

As shown in FIGS. 3 and 4, the inner tube support ring 35 has a plurality of protrusions 37A that protrude radially outward in the radial direction from the outer periphery of a support ring body 35A. The plurality of protrusions 37A may be arranged to be spaced apart from each other in the circumferential direction. The outer diameter of the inner tube support ring 35 excluding the protrusions 37A may be smaller than the inner diameter of the inward flange 17.

The inward flange 17 may include the upper inward flange 17B and the lower inward flange 17A. Grooves 17A′ opposite to the protrusions 37A of the inner tube support ring 35 are formed on the inner peripheral portion of the inward flange 17, that is, the lower inward flange 17A. As a result, the inner tube support ring 35 may be engaged with the inward flange 17 by rotating the inner tube support ring 35, such that the protrusions 37A of the inner tube support ring 35 are fitted to the grooves 17A′ of the inward flange 17.

As shown in FIG. 5, the inner tube guide ring 36 may be located below the inner tube support ring 35. The outer diameter of the inner tube guide ring 36 is formed to be greater than the inner diameter of the inward flange 17, and the inner tube guide ring 36 is in contact with the bottom surface of the inward flange 17. The inner tube guide ring 36 may be fixed to the inner tube support ring 35 with a plurality of screws 62.

Through the outer wall of the manifold 16, the exhaust pipe 19 that communicates with the exhaust space (ES of FIG. 1) is provided below the inward flange 17. A processing gas or a purge gas may be discharged through the exhaust pipe 19.

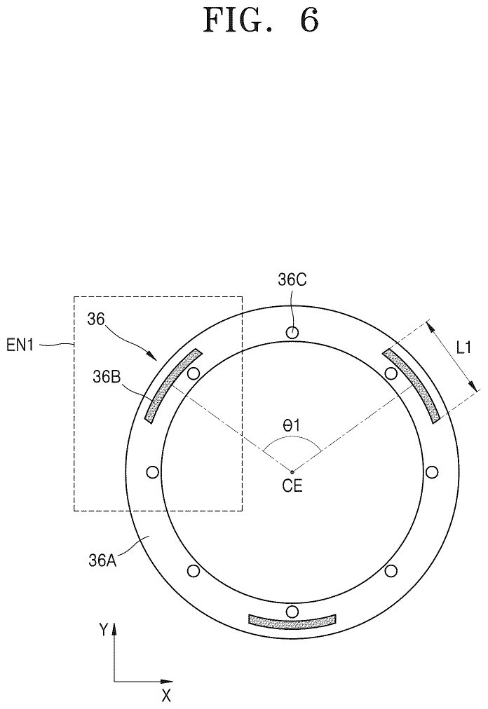

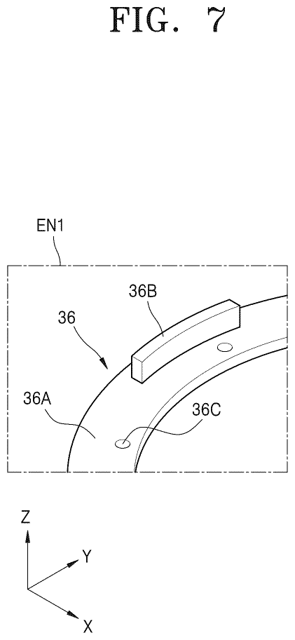

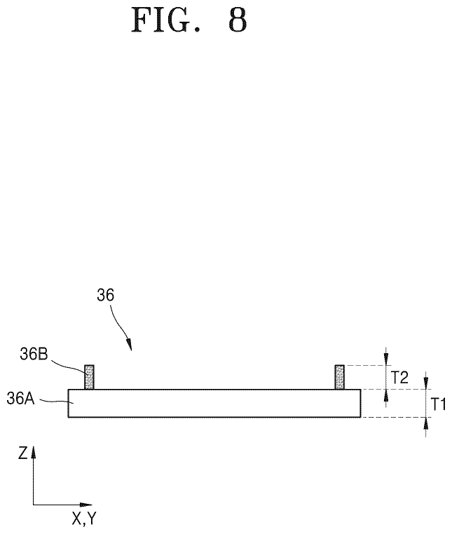

FIG. 6 is a plan view of an inner tube guide ring disposed in a manifold of the batch-type substrate processing apparatus of FIG. 1, FIG. 7 is a partially enlarged view of the inner tube guide ring portion EN1 of FIG. 6, and FIG. 8 is a partially enlarged cross-sectional view of the inner tube guide ring of FIG. 6.

Specifically, the inner tube guide ring 36 may be disposed within the manifold (16 of FIG. 1) of the batch-type substrate processing apparatus (10 of FIG. 1). The inner tube guide ring 36 may be configured in a ring-like shape.

The inner tube guide ring 36 may include the guide ring body 36A, the protrusions 36B, and screw holes 36C. The guide ring body 36A may be configured in a ring-like shape. The guide ring body 36A may have a center point CE as shown in FIG. 6. The guide ring body 36A may have a thickness T1 as shown in FIG. 8. According to one or more embodiments, the thickness T1 may be from about 1 mm to about 6 mm.

As shown in FIG. 6, a plurality of protrusions 36B, e.g., three protrusions 36B, may be arranged at equal intervals in the circumferential direction of the guide ring body 36A. The protrusion 36B may have a shape that protrudes in the vertical direction from a surface of the guide ring body 36A, as shown in FIG. 7. As shown in FIG. 8, the protrusion 36B may have a thickness T2 in the vertical direction from the surface of the guide ring body 36A. According to one or more embodiments, the thickness T2 of the protrusion 36B may be less than or equal to the thickness T1 of the guide ring body 36A. According to one or more embodiments, the thickness T2 may be from about 1 mm to about 6 mm.

According to one or more embodiments, two protrusions 36B shown in FIG. 6 may have a first central angle θ1 in the circumferential direction. The first central angle θ1 may be 120 degrees. The protrusion 36B may have a length L1 in the circumferential direction. According to one or more embodiments, the length L1 may be from about 1 mm to about 150 mm. A screw hole 36C may be a hole for fastening the guide ring body 36A to the inner tube support ring 35. A plurality of screw holes 36C, e.g., eight screw holes 36C, may be arranged to be spaced apart from one another in the circumferential direction.

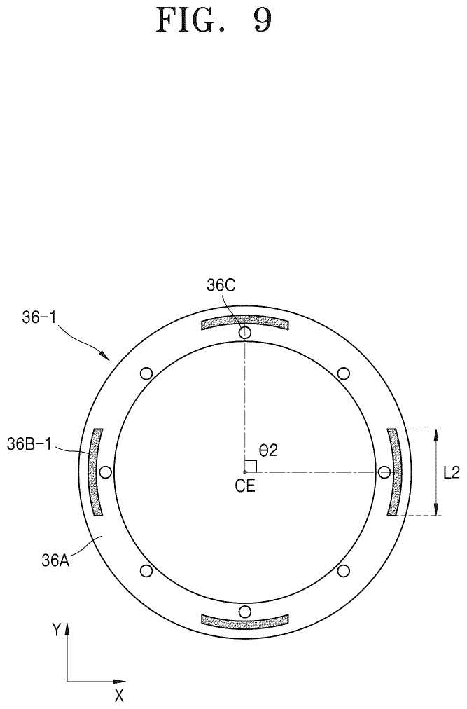

FIG. 9 is a plan view of an inner tube guide ring disposed within a manifold of a batch-type substrate processing apparatus according to an embodiment.

Specifically, an inner tube guide ring 36-1 may be identical to the inner tube guide ring 36 of FIGS. 6 to 8 except for the arrangement of protrusions 36B-1. In FIG. 9, reference numerals identical to those as in FIGS. 6 to 8 denote the same elements. In FIG. 9, descriptions identical to those given above with reference to FIGS. 6 to 8 will be briefly given or omitted.

The inner tube guide ring 36-1 may be disposed within the manifold (16 of FIG. 1) of the batch-type substrate processing apparatus (10 of FIG. 1). The inner tube guide ring 36-1 may be configured in a ring-like shape.

The inner tube guide ring 36-1 may include the guide ring body 36A, the protrusions 36B-1, and the screw holes 36C. The guide ring body 36A may be configured in a ring-like shape. The guide ring body 36A may have the center point CE.

A plurality of protrusions 36B-1, e.g., four protrusions 36B-1, may be arranged to be spaced apart from one another at equal intervals in the circumferential direction of the guide ring body 36A. Two protrusions 36B-1 may have a second central angle θ2 in the circumferential direction. The second central angle θ2 may be 90 degrees. A protrusion 36B-1 may have a length L2 in the circumferential direction. A screw hole 36C may be a hole for fastening the guide ring body 36A to the inner tube support ring 35. A plurality of screw holes 36C, e.g., eight screw holes 36C, may be arranged to be spaced apart from one another in the circumferential direction.

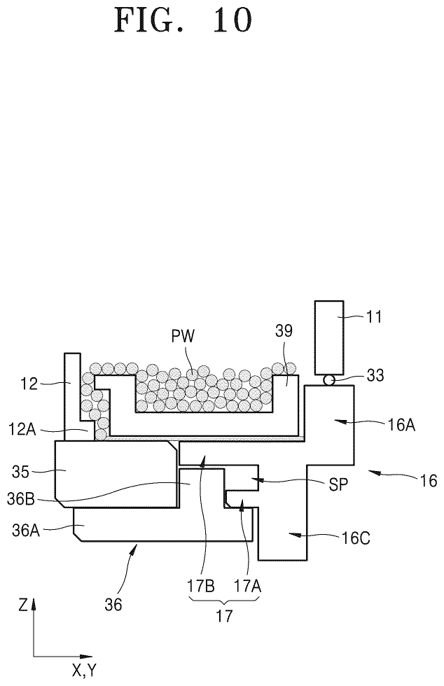

FIG. 10 is a cross-sectional view illustrating the flow of reaction by-products formed inside a manifold of a batch-type substrate processing apparatus according to the disclosure.

Specifically, the batch-type substrate processing apparatus (10 of FIG. 1) according to the disclosure may include the inner tube guide ring 36 having the protrusions 36B. The batch-type substrate processing apparatus (10 of FIG. 1) may include the manifold 16, the inner tube support ring 35, and the inner tube guide ring 36, as described above with reference to FIG. 2.

The manifold 16 may include the upper flange 16A. The outer tube 11 is supported by the upper flange 16A via the first sealant 33. The inward flange 17 is provided at the middle portion 16C of the manifold 16. The inward flange 17 may include the upper inward flange 17B and the lower inward flange 17A. There may be the empty space SP between the upper inward flange 17B and the lower inward flange 17A. The inner diameter of the upper inward flange 17B may be smaller than the inner diameter of the lower inward flange 17A.

The inner tube 12 and the inner tube flange 12A may be arranged inside the inward flange 17. The inner tube support ring 35 supporting the inner tube 12 may be disposed below the inner tube 12 and the inner tube flange 12A.

The inner tube guide ring 36 supporting the inner tube support ring 35 may be disposed below the inner tube support ring 35. The inner tube guide ring 36 may be formed to be larger than the inner diameter of the inward flange 17, that is, the lower inward flange 17A.

The inner tube guide ring 36 may be in contact with the bottom surfaces of the upper inward flange 17B and the lower inward flange 17A. The inner tube guide ring 36 may include a guide ring body 36A and a protrusion 36B protruding from the guide ring body 36A. The protrusion 36B may be located on one side of the inner tube support ring 35.

The protrusion 36B may be located on the bottom surface of the upper inward flange 17B. The outer diameter of the protrusion 36B may be smaller than the inner diameter of the lower inward flange 17A. The protrusion 36B may contact the empty space SP between the upper inward flange 17b and the lower inward flange 17A and may seal the empty space SP.

Therefore, during a manufacturing process of a semiconductor device, the protrusions 36B may prevent reaction by-products PW formed inside the process tube (14 of FIG. 1) including the inner tube 12 and the outer tube 11 from being discharged through the empty space SP between the upper inward flange 17B and the lower inward flange 17A. Therefore, components of the batch-type substrate processing apparatus (10 of FIG. 1) are not contaminated. Therefore, various components of the batch-type substrate processing apparatus (10 of FIG. 1) may be cleaned less frequently.

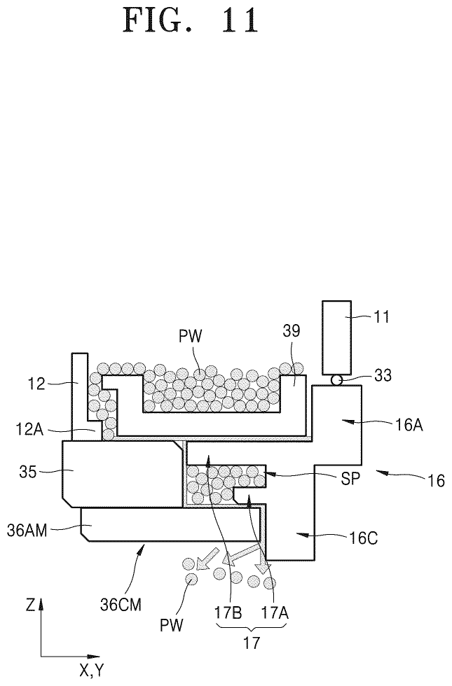

FIG. 11 is a cross-sectional view illustrating the flow of reaction by-products formed inside a manifold of a batch-type substrate processing apparatus according to a comparative example to be compared with the disclosure.

Specifically, FIG. 11 is for comparison with FIG. 10. In FIG. 11, descriptions identical to those given above with reference to FIG. 10 are omitted. The comparative example may provide the manifold 16, the inner tube support ring 35, and an inner tube guide ring 36CM.

The inward flange 17 is provided at the middle portion 16C of the manifold 16. The inward flange 17 may include the upper inward flange 17B and the lower inward flange 17A. There may be the empty space SP between the upper inward flange 17B and the lower inward flange 17A.

The inner tube 12 and the inner tube flange 12A may be arranged inside the inward flange 17. The inner tube support ring 35 supporting the inner tube 12 may be disposed below the inner tube 12 and the inner tube flange 12A.

The inner tube guide ring 36 CM supporting the inner tube support ring 35 may be disposed below the inner tube support ring 35. The inner tube guide ring 36CM may be formed to be larger than the inner diameter of the inward flange 17, that is, the lower inward flange 17A. The inner tube guide ring 36CM may include a guide ring body 36AM.

The batch-type substrate processing apparatus according to the comparative example does not include a protrusion at the inner tube guide ring 36CM. Therefore, the inner tube guide ring 36CM is unable to seal the empty space SP between the upper inward flange 17b and the lower inward flange 17A.

Therefore, during a manufacturing process of a semiconductor device, the reaction by-products PW formed inside the process tube (14 of FIG. 1) including the inner tube 12 and the outer tube 11 may be discharged through the empty space SP between the upper inward flange 17B and the lower inward flange 17A. Therefore, the batch-type substrate processing apparatus according to the comparative example has the disadvantage that reaction by-products formed while a substrate is being processed contaminate various components, and thus various components need to be cleaned more frequently.

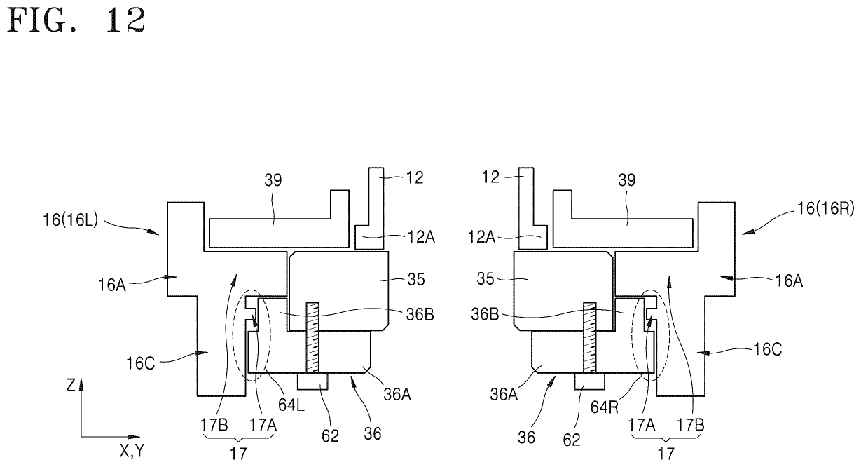

FIG. 12 is a partially enlarged cross-sectional view for schematically describing the coupling relationship between an inner tube support ring and an inner tube guide ring at a left portion and a right portion of a manifold of the batch-type substrate processing apparatus of FIG. 1.

In FIG. 12, reference numerals identical to those as in FIG. 2 denote the same elements. In FIG. 12, descriptions identical to those given above with reference to FIG. 2 are briefly given or omitted. The batch-type substrate processing apparatus (10 of FIG. 1) may include a left portion 16L and a right portion 16R of the manifold 16 in a cross-sectional view.

The manifold 16 may include the upper flange 16A. The inward flange 17 is provided at the middle portion 16C of the manifold 16. The inward flange 17 may be configured in a ring-like shape. The inward flange 17 may include the upper inward flange 17B and the lower inward flange 17A. The inner diameter of the upper inward flange 17B may be smaller than the inner diameter of the lower inward flange 17A.

The inner tube 12 and the inner tube flange 12A may be arranged inside the inward flange 17. The inner tube support ring 35 supporting the inner tube 12 may be disposed below the inner tube 12 and the inner tube flange 12A. The inner tube support ring 35 may support the inner tube 12 and the inner tube flange 12A.

According to one or more embodiments, the inner tube support ring 35 may be engaged with the inward flange 17. According to one or more embodiments, the inner tube support ring 35 may be engaged with the manifold cover 39 located on the inward flange 17. The manifold cover 39 may be omitted as needed.

The inner tube guide ring 36 supporting the inner tube support ring 35 may be disposed below the inner tube support ring 35. The outer diameter of the inner tube guide ring 36 may be formed to be greater than the inner diameter of the inward flange 17, that is, the lower inward flange 17A.

The inner tube guide ring 36 may be in contact with the bottom surfaces of the upper inward flange 17B and the lower inward flange 17A. The inner tube guide ring 36 may be fixed to the inner tube support ring 35 with the screws 62.

The inner tube guide ring 36 may include the guide ring body 36A and the protrusion 36B protruding from the guide ring body 36A. The protrusion 36B may be located on one side of the inner tube support ring 35. The protrusion 36B may be located on the bottom surface of the upper inward flange 17B. The outer diameter of the protrusion 36B may be smaller than the inner diameter of the lower inward flange 17A.

Due to the protrusion 36B, separation distances 64L and 64R between the inner tube guide ring 36 and the inner wall of the manifold 16 may become uniform along the circumference of the guide ring body 36A. Due to the protrusion 36B, the separation distances 64L and 64R between the inward flange 17 (i.e., the lower inward flange 17A) of the manifold 16 and the inner tube guide ring 36 may be adjusted to uniformly along the circumference of the guide ring body 36A.

A first separation distance 64L between the lower inward flange 17A and the inner tube guide ring 36 in the left portion 16L of the manifold 16 and a second separation distance 64R between the lower inward flange 17A and the inner tube guide ring 36 in the right portion 16R of the manifold 16 may be adjusted equally.

Therefore, the batch-type substrate processing apparatus (10 of FIG. 1) may accurately place the inner tube 12 inside the outer tube 11 and reliably perform a manufacturing process performed within the inner tube 12.

While the disclosure has been particularly shown and described with reference to embodiments thereof, it will be understood that various changes in form and details may be made therein without departing from the spirit and scope of the following claims.

What is claimed is:

1. A batch-type substrate processing apparatus comprising:
an outer tube having a cylindrical shape with a central axis disposed in a vertical direction;
an inner tube within the outer tube, the inner tube having a cylindrical shape with a central axis disposed in the vertical direction;
a manifold having a cylindrical shape, wherein the manifold supports a lower end of the inner tube and a lower end of the outer tube;
an inner tube support ring below the inner tube, wherein the inner tube support ring supports the inner tube; and
an inner tube guide ring below the inner tube support ring, wherein the inner tube guide ring supports the inner tube support ring,
wherein the inner tube guide ring comprises a guide ring body and a protrusion protruding from the guide ring body in the vertical direction, and
wherein the protrusion forms a seal between an interior of the manifold and an outer portion of the inner tube support ring.

2. The batch-type substrate processing apparatus of claim 1, further comprising a boat inside of the inner tube,
wherein the boat is configured to have a plurality of substrates mounted thereon,
wherein the batch-type substrate processing apparatus is configured to perform a substrate treatment on the plurality of substrates within the inner tube, and
wherein the substrate treatment comprises at least one of depositing a film or performing a heat treatment.

3. The batch-type substrate processing apparatus of claim 1, further comprising a boat inside of the inner tube,
wherein a length of the inner tube in the vertical direction is different from a length of the outer tube in the vertical direction, and
wherein the manifold comprises:
an upper flange that protrudes outwardly from an upper end of the manifold, wherein the upper flange supports the lower end of the outer tube; and
a lower flange that protrudes outwardly from a lower end of the manifold, wherein the lower flange is supported by a seal cap that also supports the boat.

4. The batch-type substrate processing apparatus of claim 3,
wherein the manifold comprises an inward flange having a ring-like shape, wherein the inward flange protrudes inward toward an interior of the manifold from a middle portion of the manifold, and
wherein a space between the inward flange and the seal cap forms an exhaust space configured to exhaust a gas provided during substrate processing.

5. The batch-type substrate processing apparatus of claim 1, wherein a screw fixes the inner tube guide ring to the inner tube support ring.

6. The batch-type substrate processing apparatus according to claim 1,
wherein the inner tube guide ring comprises a plurality of protrusions including the protrusion, and
wherein the plurality of protrusions are arranged in a circumferential direction along the guide ring body.

7. The batch-type substrate processing apparatus of claim 1, wherein a thickness of the protrusion is equal to or less than a thickness of the guide ring body.

8. The batch-type substrate processing apparatus of claim 1, further comprising a processing gas nozzle and a purge gas nozzle, wherein the processing gas nozzle and the purge gas nozzle extend through a sidewall of the manifold.

9. A batch-type substrate processing apparatus comprising:
an outer tube having a cylindrical shape with a central axis disposed in a vertical direction;
an inner tube within the outer tube, the inner tube having a cylindrical shape with a central axis disposed in the vertical direction;
a manifold having a cylindrical shape, wherein the manifold supports a lower end of the inner tube and a lower end of the outer tube, wherein the manifold comprises an inward flange having a ring-like shape, the inward flange protruding inward toward an interior of the manifold, and wherein the inward flange comprises an upper inward flange and a lower inward flange spaced apart from the upper inward flange in the vertical direction;
an inner tube support ring below the inner tube, wherein the inner tube support ring supports the inner tube; and
an inner tube guide ring below the inner tube support ring, wherein the inner tube guide ring supports the inner tube support ring, and wherein the inner tube guide ring is below the upper inward flange and the lower inward flange,
wherein the inner tube guide ring comprises a guide ring body and a protrusion protruding from the guide ring body in the vertical direction, and
wherein the protrusion forms a seal between an interior of the manifold and an outer portion of the inner tube support ring.

10. The batch-type substrate processing apparatus of claim 9,
wherein the inner tube guide ring further comprises a plurality of protrusions including the protrusion, and
wherein the plurality of protrusions are outside the inner tube support ring, below the upper inward flange, and inside the lower inward flange.

11. The batch-type substrate processing apparatus of claim 9, wherein an outer diameter of the inner tube guide ring is greater than an outer diameter of the inner tube support ring.

12. The batch-type substrate processing apparatus of claim 9, wherein a separation distance between an inner wall of the manifold and the inner tube guide ring is identical along a circumference of the guide ring body.

13. The batch-type substrate processing apparatus of claim 9, further comprising a boat inside of the inner tube,
wherein a space between the inward flange and a seal cap supporting the boat forms an exhaust space configured to exhaust a gas provided during substrate processing.

14. The batch-type substrate processing apparatus of claim 9,
wherein the inner tube guide ring comprises a plurality of protrusions including the protrusion, and
wherein the plurality of protrusions are arranged in a circumferential direction along the guide ring body in 120 degree intervals.

15. The batch-type substrate processing apparatus of claim 9,
wherein the inner tube guide ring comprises a plurality of protrusions including the protrusion, and
wherein the plurality of protrusions are arranged in a circumferential direction along the guide ring body in 90 degree intervals.

16. A batch-type substrate processing apparatus comprising:
an outer tube having a closed upper end and a cylindrical shape with a central axis disposed in a vertical direction;
an inner tube inside of the outer tube, the inner tube having a closed upper end and a cylindrical shape with a central axis disposed in the vertical direction, wherein an annular space is formed between the inner tube and the outer tube, and wherein a length of the inner tube in the vertical direction is different from a length of the outer tube in the vertical direction;
a manifold having a cylindrical shape, wherein the manifold supports a lower end of the inner tube and a lower end of the outer tube, and wherein the manifold comprises:
an upper flange, the upper flange protruding outward from the manifold and supporting the lower end of the outer tube at an upper end of the manifold; and
an inward flange having a ring-like shape, the inward flange protruding inward toward an interior of the manifold from a middle portion of the manifold, wherein the inward flange comprises an upper inward flange and a lower inward flange spaced apart from the upper inward flange in the vertical direction;
an inner tube support ring below the inner tube, wherein the inner tube support ring supports the inner tube; and
an inner tube guide ring below the inner tube support ring, wherein the inner tube guide ring supports the inner tube support ring,
wherein the inner tube guide ring is below the upper inward flange and the lower inward flange,
wherein the inner tube guide ring comprises a guide ring body and a protrusion protruding from the guide ring body in the vertical direction, and
wherein the protrusion forms a seal between an interior of the manifold and an outer portion of the inner tube support ring.

17. The batch-type substrate processing apparatus of claim 16, wherein a separation distance between the lower inward flange of the manifold and the inner tube guide ring is identical along a circumference of the guide ring body.

18. The batch-type substrate processing apparatus of claim 16, further comprising a boat inside of the inner tube,
wherein the manifold further comprises a lower flange protruding outward from a lower end of the manifold, wherein the lower flange is supported by a seal cap that also supports the boat.

19. The batch-type substrate processing apparatus of claim 16, further comprising a processing gas nozzle and a purge gas nozzle,
wherein the processing gas nozzle extends through a sidewall of the manifold and is configured to supply a processing gas into the inner tube, and
wherein the purge gas nozzle extends through the sidewall of the manifold and is spaced apart from the processing gas nozzle, wherein the purge gas nozzle is configured to supply a purge gas into the annular space between the inner tube and the outer tube.

20. The batch-type substrate processing apparatus according to claim 16,
wherein the inner tube guide ring further comprises a plurality of protrusions including the protrusion, and
wherein the plurality of protrusions are arranged in a circumferential direction along the guide ring body at equal intervals.
